(19) United States
(12) Patent Application Publication
(10) Pub. No.: US 2004/0227142 A1
(43) Pub. Date: Nov. 18, 2004

(54) Light-emitting semiconductor device

(75) Inventor: Toshihide Izumiya, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/798,479

(22) Filed: Mar. 12, 2004

(30) Foreign Application Priority Data
Mar. 13, 2003 (JP) P2003-068556

(51) Int. Cl. H01L 27/15

(52) U.S. Cl. 257/79

(57) ABSTRACT

A light-emitting semiconductor device is made of a first reflection film, an active layer, a second reflection film, an electric current spreading layer, a contact layer, and a high resistance region in order. The first reflection film reflects light with a wavelength λ. The active layer is injected with electric current to emit light with a wavelength of about λ. The second reflection film reflects the light with the wavelength λ. The second reflection film has a periodical structure alternately stacked with a first semiconductor layer and a second semiconductor layer. A reflectivity with respect to the light with the wavelength λ of the second reflection film is lower than that of said first reflection film. The electric current spreading layer transmits the light with the wavelength λ. The electric current spreading layer is the same electronic conduction type as the second reflection film and has not less than half of a thickness of the second reflection film. The contact layer formed is the same electronic conduction type as the second reflection film. The high resistance region is formed in a part of the second reflection film. The light-emitting semiconductor device is capable of operating at a speed of not less than 500 Mbps.

### FIELD OF THE INVENTION

This invention generally relates to a light-emitting semiconductor device and, more particularly, to a resonant cavity type light-emitting semiconductor device.

This application is based upon and claims the benefit of priority from the prior Japanese Patent Application No. 2003-68556, filed on Mar. 13, 2003, the entire contents of which are incorporated herein by reference.

### BACKGROUND OF THE INVENTION

A light-emitting diode (LED) or semiconductor laser (LD) to which III-V compound semiconductors are applied has been widely utilized for optical communication, multi-media devices and display panels. The development in the field of the optical communication is rapid to support the IT infrastructure. Optical communication generally means a long distance, large capacity optical communication system for which quartz optical fibers and infrared optical devices are used. In these several years, however, a short distance optical communication system has been in the limelight. This optical communication system covers a distance ranging from 10 m to 100 m and consists of visible wavelength optical devices. This is because a polymer-based optical fiber (POF) has been developed so that it makes visible light transmission possible and easy. To date, verification is progressively carried out for a short distance optical communication system for which the III-V compound semiconductor optical devices set forth above are used and which communicates in a short range from 10 m to 100 m at a transmission rate from 500 Mbps to 1 Gbps.

As the III-V compound semiconductor optical device, a resonant cavity type light-emitting diode (RC type LED) is expected to be used for a visible short distance optical communication with a transmission rate on the order of 500 Mbps (e.g., IEEE 1394). The RC type LED has features that may be compared to intermediate ones defined between a laser diode and a light-emitting diode, and a great expectation for its high speed-response.

An LED with the same structure as provided for a display LED has been employed as a light-emitting semiconductor device used for optical communication at a transmission rate of 125 Mbps or so because it is less expensive. Since the LED, however, is most likely to have a limit to a transmission rate of 250 Mbps or so, it has a problem on the high-speed response. Only from a viewpoint of the high-speed response, an LD used as the light-emitting element is superior. The LD has other problems because it is expensive and its temperature characteristic is poor. Thus, there is a great expectation for the RC type LED as a light-emitting element of a visible short distance optical communication system. The RC type LED is disclosed in Japanese Unexamined Patent Publication Nos. 2002-76433 and 2002-111054.

The RC type LED, however, has the other problems that the output power is relatively low and the receiving signal becomes weak in the case that it is used for optical communication at a transmission rate of 500 Mbps or more. In other words, it is quite difficult to provide the RC type LED with both high-speed response and increasing output power.

If the light-emitting area of a light emitting element is reduced to make the element capacity smaller, the element response speed becomes higher but the optical output power usually becomes lower. Conversely, however, if the element is made larger in size or a narrow electric current path structure or ridge structure is made for the element, the output power becomes higher but it is difficult to achieve a higher response speed. Namely, it is difficult to cope with both high-speed response and increasing output power required for the light-emitting element. Thus, if a high-speed operation is given priority so that an RC type LED is designed to operate at a transmission rate of 500 Mbps or more, its output power becomes lower.

### SUMMARY OF THE INVENTION

Accordingly, the present invention is for solving the problem set forth above and provides a resonant cavity type light-emitting semiconductor device with both high response speed and high output power.

One aspect of the present invention is directed to a light-emitting semiconductor device made of a first reflection film, an active layer, a second reflection film, an electric current spreading layer, a contact layer, and a high resistance region in order. The first reflection film reflects light with a wavelength λ. The active layer is injected with electric current to emit light with a wavelength of about λ. The second reflection film that reflects the light with the wavelength λ has a periodical structure stacked with alternate pairs of first and second semiconductor layers. A refraction index with respect to the light with the wavelength λ of the second reflection film is lower than that of the first reflection film. The electric current spreading layer that transmits the light with the wavelength λ is the same electronic conduction type as the second reflection film and has not less than half of a thickness of the second reflection film. The contact layer formed is the same electronic conduction type as the second reflection film. The high resistance region is formed in a part of the second reflection film.

### BRIEF DESCRIPTION OF THE DRAWINGS

A more complete appreciation of the present invention and many of its attendant advantages will be readily obtained as the same becomes better understood by reference to the following detailed descriptions when considered in connection with the accompanying drawings, wherein:

FIG. 1 is a cross-sectional view of a light-emitting semiconductor device in accordance with the first embodiment of the present invention;

FIG. 2 is a cross-sectional view of a comparison sample RC type LED;

FIG. 3 is a cross-sectional view of a light-emitting semiconductor device in accordance with the second embodiment of the present invention;

FIG. 4 is a cross-sectional view of a light-emitting semiconductor device in accordance with the third embodiment of the present invention;

FIG. 5 is a cross-sectional view of a light-emitting semiconductor device in accordance with the fourth embodiment of the present invention;

FIG. 6 is a cross-sectional view of a light-emitting semiconductor device in accordance with the fifth embodiment of the present invention; and

FIG. 7 is a cross-sectional view of a light-emitting semiconductor device in accordance with the sixth embodiment of the present invention.

### DESCRIPTION OF THE EMBODIMENTS

Embodiments of the present invention will be explained below with reference to the attached drawings. It should be noted that the present invention is not limited to the embodiments but covers their equivalents. Throughout the attached drawings, similar or same reference numerals show similar, equivalent or same components. The drawings, however, are shown schematically for the purpose of explanation so that their components are not necessarily the same in shape or dimension as actual ones. In other words, concrete shapes or dimensions of the components should be considered as described in these specifications, not in view of the ones shown in the drawings. Further, some components shown in the drawings may be different in dimension or ratio from each other.

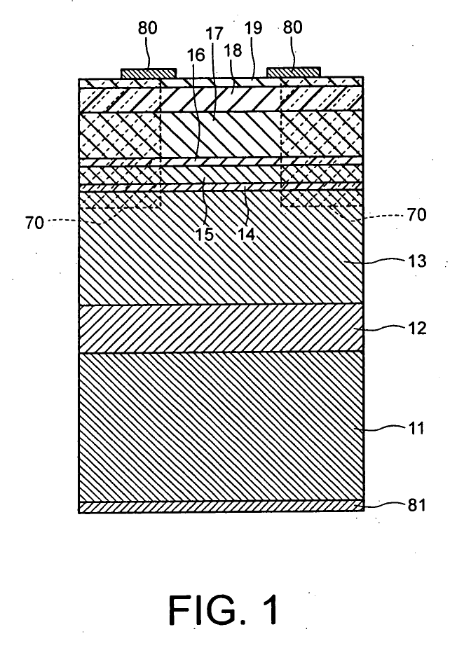

Embodiments of a light-emitting semiconductor device of the present invention will be explained below with reference to the attached drawings. The light-emitting semiconductor device is made of a first reflection film, a light-emitting layer including an active layer, a second reflection film, an electric current spreading layer, a contact layer, and a high resistance region in order. One of structural features of the embodiments is that as shown in FIG. 1, for instance, the light-emitting semiconductor device is provided with high resistance regions 70 partially provided in the second reflection film 17 and electric current spreading layer 18 formed on the second reflection film 17. With the structure, high resistance regions 70 decrease capacitance of the light-emitting semiconductor device so that a high-speed operation can be achieved. Further, electric current spreading layer 18 uniformly injects electric current from p-side electrode 80 into active layer 15 to increase its optical output. Thus, the present invention provides a resonant cavity type light emitting diode (RC type LED) that can operate at a high-speed of 500 Mbps or more and emits high output light. Six embodiments of the present invention will be explained below with reference to FIGS. 1-7.

### First Embodiment

FIG. 1 is a cross-sectional view of an RC type LED in accordance with the first embodiment. The RC type LED is used for optical communication at a transmission rate of 500 Mbps or more. Its wavelength is 660 nm, which has little transmission loss in the POF available at present.

The RC type LED shown in FIG. 1 is provided with GaAs substrate 11, n-type GaAs buffer layer 12, n-type lower distributed Bragg reflector (DBR: the first reflection film) 13, n-type clad layer 14, active layer 15, p-type clad layer 16, and p-type upper distributed Bragg reflector (DBR: the second reflection film) layer 17. DBR layer 13 is made of 50 pairs of AlxGa₁-xAs, (x=0.50), and AlyGa₁-yAs, (y=0.95), which are alternately stacked with each other. N-type clad layer 14 is made of InGaAlP based materials while active layer 15 used as a light-emitting layer is a multiple-quantum-well (MQW) structure consisting of InGaAlP based materials. P-type upper DBR layer 17 is made of 12 pairs of AljGa₁-jAs, (j=0.50), and AlkGa₁-kAs, (k=0.95), which are alternately stacked with each other. Further, electric current spreading layer 18 is made of 600 nm thick AlzGa₁-z, (z=0.7) that is formed on DBR layer 17. Electric current spreading layer 18 provided is one of the technical features of the RC type LED shown in FIG. 1. Carrier concentrations of electric current spreading layer 18 range from 1.0×10¹⁸/cm³ to 4.0×10¹⁸/cm³. P-type contact layer 19 made of 20 nm thick GaAs is formed on electric current spreading layer 18. The multiple layers from n-type DBR layer 13 through contact layer 19 are partially provided with high resistance region 70 formed with proton implantation. The lateral width of the region into which no proton is implanted, i.e., that of light emitting portion shown in FIG. 1, is 50 μm. P-side electrode (electrode metal) 80 is formed on a part of contact layer 19. Another electrode of n-side electrode 81 is formed at the bottom side of GaAs substrate 11 as shown in FIG. 1.

The semiconductor layers 12-19 of the RC type LED shown in FIG. 1 are deposited with a metal organic chemical vapor deposition (MOCVD) method, for instance. Materials used for such deposition are as follows: trimethylindium (TMI) for In, trimethylgallium (TMG) for Ga, trimethylaluminum (TMA) for Al, arsine (AsH₃) for As, and monomethyl hydrazine (MMH) for N. Material for n-type dopant is silane (SiH₄) while that for p-type dopant is dimethylzinc (DMZ) or carbon tetrabromide (CBr₄). Particularly, the carbon tetrabromide is applied to the p-type dopant material for AlGaAs upper DBR layer 17 and electric current spreading layer 18 because, preferably, their p-type dopant is carbon. If carbon is employed for the dopant of DBR layer 17 and electric current spreading layer 18 consisting of AlGaAs, the p-type dopant is not only highly doped but also difficult to diffuse into active layer 15. As a result, high properties are provided to the RC type LED. After the deposition of semiconductor layers 12-19, high resistance region 70 is formed with proton implantation, and p-side electrode 80 and n-side electrode 81 are then formed so that the RC type LED shown in FIG. 1 is produced.

In the RC type LED shown in FIG. 1, electric current is injected for active layer 15 to emit light with a wavelength in the vicinity of 660 nm. The light is reflected and resonated between upper and lower DBR layers 13 and 17 so that their photo-recycling effect narrows a radiation spectrum width up to about 5.5 nm. In the light emitting device shown in FIG. 1, lower DBR layer 13 is at a high reflectivity of 99.95% with respect to light emitted from active layer 15 but upper DBR layer 17 is at a low reflectivity of about 95%. Thus, resonated light is irradiated to the upper side shown in FIG. 1 through the low reflective upper DBR layer 17.

Here, as shown in FIG. 1, the RC type LED is a semiconductor device that includes active layer 15 and reflection films 13 and 17 provided on both sides of active layer 15 so that the semiconductor device causes a photo-recycling effect and generates resonant light between reflection films 13 and 17. If a reverse distribution of carriers takes place and the resonance becomes much stronger, a surface emitting laser device will be constituted. Since the reflectivity of reflection films 13 and 17 of the RC type LED, however, is not higher than that of the surface emitting laser device, no laser oscillation (induced emission) is caused. The surface emitting laser device is used in optical communication required for not less than 4 Gbps operation, for example, in which the spectrum width is required to be narrow up to 1 nm. The spectrum width of approximately 6 nm is good enough in the case of optical communication required for operation speeds of 500 Mbps-1 Gbps. In other words, the RC type LED shown in FIG. 1 also complies with such requirements. In the RC type LED, although an optical amplification effect (photo-recycling effect) decreases as the reflectivity of reflection film 17 on the light-emitting side decreases, the emission of light to the outside becomes easier. Thus, if the number of paired layers for reflection film 17 on the light-emitting side is reduced to an appropriate value, optical output becomes higher. In this embodiment, the number of the paired layers for the first reflection film 13 is 50 but that for the second reflection film 17 (reflection film on the light-emitting side) is reduced to 12 to make the output higher.

Since the RC type LED shown in FIG. 1 is provided with high resistance region 70 formed with implantation of protons into parts of n-type DBR layer 13 through contact layer 19, the device decreases in capacitance but increases in capability of high-speed operation.

Since the device is further provided with 600 nm thick electric current spreading region 18, it increases in optical output. The applicant understands that, with electric current spreading layer 18, the electric current departing from p-side electrode 80 to active layer 15 is sufficiently diffused in the lateral direction shown so that the current is uniformly injected into active layer 15.

It is, however, contrary to the common knowledge for those skilled in the semiconductor art that 600 nm electric current spreading layer 18 can be provided for the RC type LED required for high-speed operation of not less than 500 Mbps. It is because they thought that such thick electric current spreading layer 18 would change the reflection characteristics of upper DBR17 so that it would diminish the photo-recycling effect. Nevertheless, the applicant has obtained good results from an experiment of the RC type LED shown in FIG. 1 operated at the speed of 1 Gbps. The applicant believes that uniformly injected current brings uniform simultaneous light emission so that the rise time of the pulse response becomes short. This effect improves the response of the devices. Current spreading layer 18 never changes the resistance and capacitance. As a result, although electric current spreading layer 18 is provided, the RC type LED shown in FIG. 1 can operates at the speed of 1 Gbps.

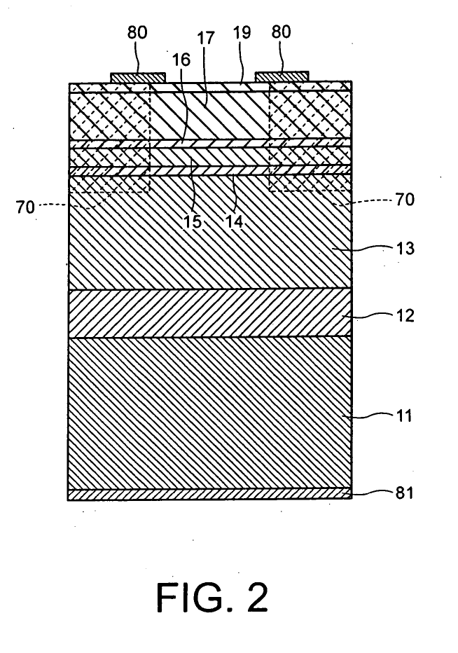

As described above, since electric current spreading layer 18 and high resistance region 70 are provided in the LED shown in FIG. 1, the device can increase in optical output while maintaining a high-speed operation. More concretely, when the device shown in FIG. 1 was tested at the operation speed of 500 Mbps, the device proved to have device resistance of 10 Ω, device capacitance of 3 pF, rise time of not more than 2 nsec for emitting light driven by pulses and fall time of not more than 1 nsec. The device shown in FIG. 1 increased in output by not less than 10% compared with an RC type LED not provided with electric current spreading layer 18 as shown in FIG. 2. In other words, the provision of electric current spreading layer 18 can increase in optical output by not less than 1.1 times.

Further, in the RC type LED shown in FIG. 1, DBR layers alternately, periodically stacked with pairs of high reflective layer of Al_{0.50}G_{0.50}As and low reflective layer of Al_{0.95}Ga_{0.05} are used as reflection films 13 and 17. Reflection is enhanced by reflection films 13 and 17 with ¼λ stack layers. The periodical structure is set to the period of half or ⅛ of a wavelength of emitting light, variations of ¼λ stack, so that the device can effectively reflect the light emitted from active layer 15.

Since a DBR layer consisting of AljGa₁-jAs/AlkGa₁-kAs like DBR layer 17 shown in FIG. 1 has a lattice constant close to that of GaAs substrate 11 or active layer 15, the DBR layer is generally used for InGaAlP-based light-emitting devices. Thus, the property and manufacturing methods of DBR layer 17 are well known so that it is easy to design and produce the DBR layer. A layer alternately stacked with two similar kinds of films reduces thermal and electrical resistance and is easier to make intermediate layers inserted between the two kinds of films.

Although the RC type LED shown in FIG. 1 is provided with electric current spreading layer 18 consisting of 600 nm thick AlzGa₁-zAs, (z=0.7), the thickness and Al composition z can be changed. In the case that optical output is improved, the thickness is thick and Al composition z is high. Inversely, when moisture resistance is increased, Al composition z is set to be low, provided, however, that it is preferable to set Al composition z to be not less than 0.5 to prevent electric current spreading layer 18 from absorbing light emitted from active layer 15. In order to obtain the optical output increasing effect set forth above, it is desirable to set the thickness of electric current spreading layer 18 not to be less than half of that of upper DBR layer 17.

In the RC type LED shown in FIG. 1, a DBR layer alternately, periodically stacked with the first semiconductor layer of AljGa₁-jAs, (j=0.50) and the second semiconductor layer of AlkGa₁-kAs, (k=0.95) is used for the second reflection film 17. Al compositions j and k can be changed, provided, however, that low Al composition j for the first semiconductor layer is preferably set not to absorb light emitted from active layer 15. Al composition difference, i.e., refraction index difference, (k-j) for both layers is preferably set to be high in order to make the reflectivity high against light emitted from active layer 15.

Further, in the RC type LED shown in FIG. 1, a DBR layer alternately, periodically stacked with 50 pairs of the layers of AlxGa₁-xAs, (x=0.50) and AlyGa₁-yAs, (y=0.95) is used for the first reflection film 13. If necessary, however, the first reflection film 13 can consist of another reflection film with a reflectivity of 99.9% against light emitted from active layer 15.

The explanation set forth above for better understanding is on the assumption that resonance wavelength λ FP is substantially equal to photoluminescent (PL) light-emitting wavelength λ PL (the wavelength of the light emitted from the active layer). Strictly speaking, they are somewhat different values. Concretely, an RC type LED is generally set to Δ=λFP−λPL=5˜10 nm. This is because heat generation makes the wavelength λ PL longer. In other words, strictly speaking, the active layer in the RC type LED emits light with a wavelength (λ FP-Δ) if the resonant wavelength of the first and second reflection films 13 and 17 is set to λ FP. Namely, the light emitted from the device has a wavelength of about λ FP.

### Second Embodiment

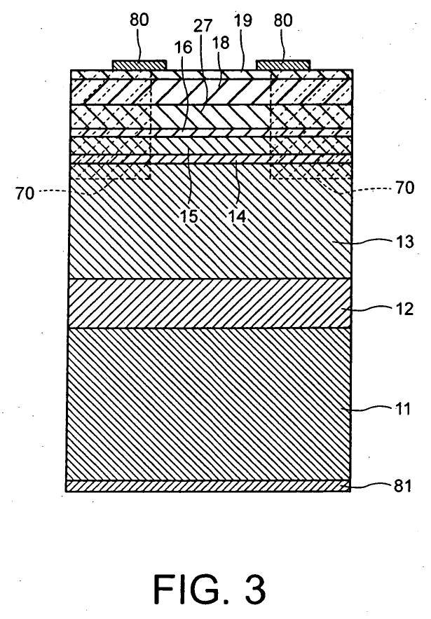

An RC type LED of the second embodiment is shown in FIG. 3. The structural differences between the first and second embodiments are that the number of the first and second semiconductor layers for upper DBR layer 27 is reduced to 6 pairs and the thickness of upper DBR layer 27 is set to be thinner up to about 600 nm. With this structure, the LED can increase higher in output. Except for the number of paired layers for upper DBR layer 27 and the thickness, the second embodiment is substantially the same in structure as the first one (shown in FIG. 1).

FIG. 3 is a cross-sectional view of the RC type LED in accordance with the second embodiment of the present invention. Upper DBR layer 27 formed on p-type clad layer 16 is alternately stacked in structure with a high reflective layer of AljGa₁-jAs, (j=0.50), and a low reflective layer of AlkGa₁-kAs, (k=0.95), as in the first embodiment (shown in FIG. 1). The last (top) layer is the high reflective layer of AljGa1-jAs, (j=0.50). The thickness of DBR layer 27 is about 600 nm which is approximately half of that of DBR layer 17 shown in FIG. 1. In order to increase the reflectivity of upper DBR layer 27, the farthest (top) layer from active layer 15 is the high reflective layer (Al_{0.50}Ga_{0.50}As). Since the top layer of DBR layer 27 is made of a lower Al composition material, the moisture-resistance property of DBR layer 27 is improved. The thickness of electric current spreading layer 18 formed on upper DBR layer 27 is 600 nm. Contact layer 19 is formed on electric current spreading layer 18.

Since the number of the paired layers for DBR layer 27 in RC type LED shown in FIG. 3 is reduced to 6, the optical output is higher than that of the device shown in FIG. 1. Analytically, the reduction of the number of the paired layers for DBR layer 27 makes the light easily emit to the outside. Further, electric current spreading layer 18 is provided so that, although DBR layer 27 is set to be thinner in thickness, electric current from p-side electrode 80 to active layer 15 is expanded in the lateral direction shown in FIG. 3 and is uniformly injected into active layer 15. More concretely, the optical output of the device shown in FIG. 3 is about 1.2 times that of the comparison sample device shown in FIG. 2 while it is about 1.1 times that of the device shown in FIG. 1.

In addition, since the number of paired layers for upper DBR layer 27 is reduced in the device shown in FIG. 3, the heat resistance becomes lower and the temperature characteristic is improved.

Although the reduction of the number of paired layers for DBR layer 27 in the device shown in FIG. 3 leads to a wider spectrum width up to 6 nm, it does not affect a short distance optical communication system employing the POF.

The number of the paired layers for DBR layer 27 of the RC type LED shown in FIG. 3 is 6 as described above but it ranges from 4 through 11, preferably, from 4 through 8 to obtain the effect of increase in optical output.

### Third Embodiment

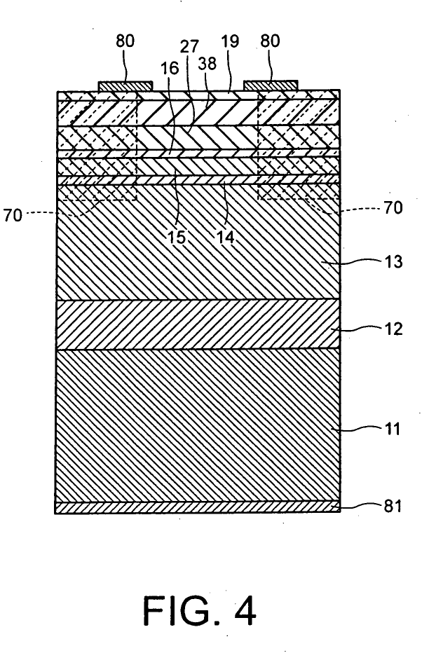

A structural difference between the third embodiment shown in FIG. 4 and the second embodiment shown in FIG. 3 is that electric current spreading layer 38 is made of Zn doped In_{0.5}(Ga_{0.5}Al_{0.5})_{0.5}P. Since the other structures of the third embodiment are substantially the same as those of the second one (FIG. 3), their detailed explanation is omitted.

A manufacturing method of the RC type LED shown in FIG. 4, preferably, uses dimethylzinc (DMZ) for a p-type dopant material for electric current spreading layer 38 and zinc for a p-type dopant. In the case that zinc is used as a p-type dopant for the layer 38, the p-type dopant is highly doped.

Since electric current spreading layer 38 in the RC type LED shown in FIG. 4 is made of In_{0.5}(Ga_{0.5}Al_{0.5})_{0.5}P, its oxidation resistance is improved in comparison with the second embodiment (FIG. 3). Here, as electric current spreading layer 38 becomes thicker in thickness, it ought to improve in oxidation resistance. Since electric current spreading layer 38 is different in material from the second reflection film 27 made of AlGaAs, it is difficult to grow a thick crystal for electric current spreading layer 38. Thus, the thickness of electric current spreading layer 38 ranges desirably from 0.5 μm through 2 μm.

Although the second reflection film 27 in the RC type LED shown in FIG. 4 is different in material from electric current spreading layer 38, increase in device resistance can be suppressed and a high-speed operation can also be achieved at not less than 500 Mbps. Analytically, it results from the fact that continuous crystal growth can be carried out for both upper DBR layer 27 and electric current spreading layer 38 and that, since continuous layers 27 and 38 are made to contain Al, it is hard to increase device resistance at an interface defined between the layers 27 and 38.

Electric current spreading layer 38 of the RC type LED shown in FIG. 4 consists of In_{d}(Ga₁-_{c}Al_{c})_{1-d}P, (c=0.5, d=0.5). If c=d=0.5 or its approximation, the device can improve in oxidation resistance. The optimum composition, however, changes in accordance with wavelengths of the light emitted from active layer 15.

### Fourth Embodiment

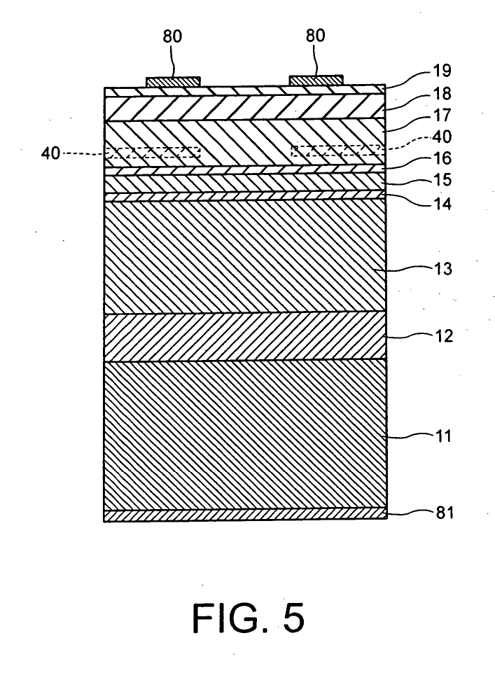

FIG. 5 is a cross-sectional view of a RC type LED in accordance with the fourth embodiment of the present invention. The wavelength of light is set at the same of 660 nm as in the first embodiment (FIG. 1). A difference between this device and the first embodiment (FIG. 1) is that high resistance region 40 is formed by implementing selective oxidation of a part of the second reflection film 17 with steam.

In the device shown in FIG. 5, continuous crystal growth can be carried out for DBR layer 17, electric current spreading layer 18 and contact layer 19 in substantially the same way as in the first embodiment (FIG. 1). Thus, the provision of electric current spreading layer 18 results in little increase in device resistance so that a high-speed operation can be achieved as that of the first embodiment.

The device shown in FIG. 5 is somewhat complicated in structure and manufacturing process, and is relatively hard from uniformity and reproducibility. An oxide layer (AlOx) of high resistance region 40 is so small in refraction index to advantageously produce a lens effect. Thus, the output can be high in a low electric current region while the operation voltage is kept low. Further, the spectrum width can be narrow at 5 nm.

### Fifth Embodiment

The descriptions of the first through fourth embodiments are so far directed to the light-emitting devices with a wavelength of 660 nm corresponding to light transmissions (optical communication) employing plastic optical fibers (POF). The fifth embodiment, however, will be related to a light-emitting device with a wavelength of 1.25 μm corresponding to light transmissions employing quartz optical fibers.

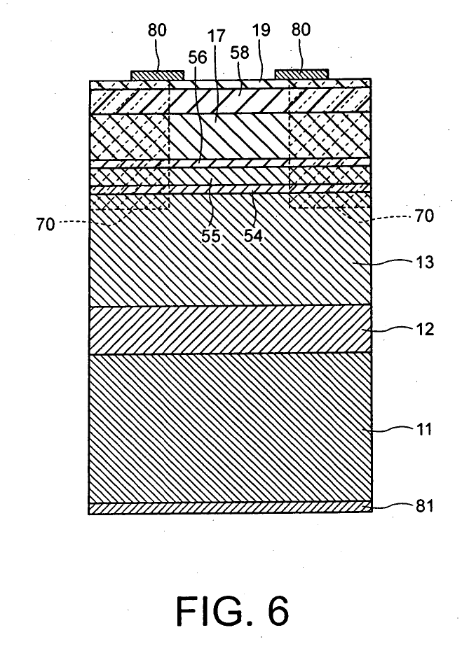

FIG. 6 is a cross sectional view of an infrared light-emitting RC type LED in accordance with the fifth embodiment of the present invention. The RC type LED is provided with GaAs substrate 11 on which n-type GaAs buffer layer 12, n-type lower DBR layer 13, n-type AlGaAs clad layer 54, 2% nitrogen GaInNAs active layer 55, p-type AlGaAs clad layer 56, p-type upper DBR layer 17, p-type GaAs electric current spreading layer 58, and p-type GaAs contact layer 19 are formed in order.

Active layer 55 in the light-emitting device shown in FIG. 6 has a single quantum well structure of AlGaAs that emits infrared light with a wavelength of 1.25 μm. Clad layers 54 and 56 each are made of AlGaAs, consistent with the material for active layer 55. The thickness of contact layer 19 is 20 nm but that of electric current spreading layer 58 is set to 1.0 μm to improve electric current spreading layer effects. Electric current spreading layer 58 is made of narrow bandgap GaAs to lower an operation voltage, to improve moisture resistance and to make a high-speed operation possible. Although electric current spreading layer 58 is thick in thickness and small in bandgap, the infrared light passes through GaAs layer 58 so that the light emitted from active layer 55 is not absorbed by electric current spreading layer 58.

The cost of the light-emitting device shown in FIG. 6 can be reduced significantly in comparison with that of a laser diode (LD). Operation electric current concentration of the light-emitting device can be lower than that of the LD. In addition, reduction of heat effects makes an operation possible at a higher temperature. The light-emitting device, however, is wider in spectrum and slower in operation speed than the LD. The RC type LED shown in FIG. 6 or the LD are determined for applications in light of the above technical features.

The RC type LED shown in FIG. 6 emits infrared light with a wavelength of 1.25 μm by way of example but it is possible to lengthen the wavelength up to 1.35 μm with a change in N mixture quantity of active layer 55.

A quartz fiber is used for the RC type LED shown in FIG. 6 but a POF will be used in place of the quartz fiber if the POF with little loss in the infrared region is developed.

### Sixth Embodiment

The sixth embodiment of the present invention is directed to an RC type LED with a wavelength of 0.98 μm.

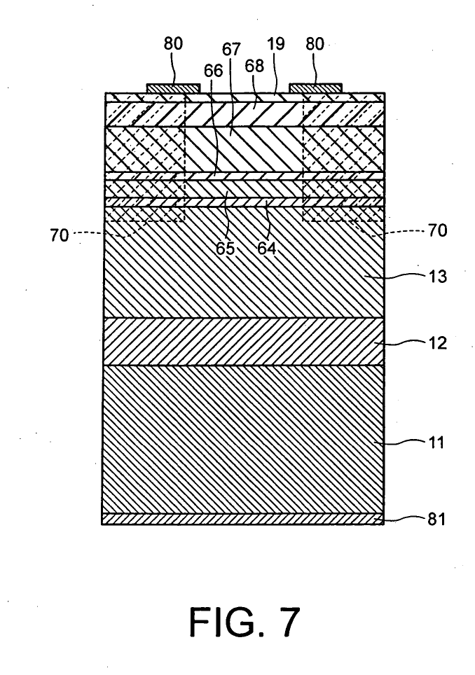

FIG. 7 is a cross-sectional view of the RC type LED in accordance with the sixth embodiment of the present invention. The RC type LED is provided with GaAs substrate 11 on which n-type GaAs buffer layer 12, n-type lower DBR layer (first reflection film) 63, n-type Al_{0.2}Ga_{0.8}As clad layer 64, InGaAs based active layer 65, p-type Al_{0.2}Ga_{0.8}As clad layer 66, p-type upper DBR layer (the second reflection film) 67, p-type GaAs electric current spreading layer 68, and 0.5 μm thick p-type GaAs contact layer 19 are formed in order.

Active layer 65 in the light-emitting device shown in FIG. 7 has a multiple quantum well structure of InGaAs that emits light with a wavelength of about 0.98 μm. Clad layers 64 and 66 each are made of AlGaAs based material, consistent with that for active layer 65. Each of the first and second reflection films 63 and 67 is stacked with layers of AljGa₁-jAs, (j=0), and AlkGa₁-kAs, (k=0.97) to make the difference of refraction indexes large. Although GaAs is used for ones of the two stacked layers for the first and second reflection films 63 and 67 as set forth above, the light-emitting device shown in FIG. 7 emits infrared light with a wavelength of about 0.98 μm, which is not absorbed by the GaAs layer. Further, electric current spreading layer 68 is also made of GaAs.

In comparison with the LD, the RC type LED shown in FIG. 7, which is similar to that shown in FIG. 6, can be substantially less expensive in cost, have an operation electric current that is lower in concentration, be less affected by heat, and have a longer life. Thus, whether to use the RC type LED shown in FIG. 7 or the LD is also determined in light of the nature of applications.

A POF will be used for the RC type LED shown in FIG. 7 if the POF with low loss of infrared spectrum region is developed.

The first through sixth embodiments of the present invention have been described above. It is understood that the present disclosure of the preferred forms has been changed in the details of construction and the combination and arrangement of components may be resorted to without departing from the spirit and the scope of the invention as hereinafter claimed. The material for the active layer, for instance, may be changed. More concretely, N (nitrogen) is mixed in the active layer so that energy discontinuity on the conduction band can be increased in the case that a heterojunction is formed, so that overflow of electrons can be reduced and so that temperature characteristics can be improved.

According to the present invention, since an RC type LED basically consisting of a first reflection film, an active layer and a second reflection film further includes a high resistance region formed a part of the second reflection film to decrease a device capacitance and an electric current spreading layer formed on the second reflection film, it can provide the RC type LED with a high operation speed and high output features.

What is claimed is:

1. A light-emitting semiconductor device comprising:
a first reflection film to reflect light with a wavelength λ;
a light emitting layer formed on said first reflection film, said light-emitting layer being injected with electric current to emit light with a wavelength of about λ;
a second reflection film formed on said light-emitting layer to reflect the light with the wavelength λ, said second reflection film being provided with a periodical structure alternately stacked with a first semiconductor layer and a second semiconductor layer, wherein a reflectivity with respect to the light with the wavelength λ of said second reflection film is lower than that of said first reflection film;
an electric current spreading layer formed on said second reflection film to transmit the light with the wavelength λ, said electric current spreading layer being the same electronic conduction type as said second reflection film and having not less than half of a thickness of said second reflection film;
a contact layer formed on said electric current spreading layer, said contact layer being the same electronic conduction type as said second reflection film; and
a high resistance region formed in a part of said second reflection film.

2. A light-emitting semiconductor device according to claim 1, wherein said light-emitting semiconductor device is capable of operating at a speed of not less than 500 Mbps.

3. A light-emitting semiconductor device according to claim 1, wherein said first semiconductor is made of a III-V group compound semiconductor and said second semiconductor is made of a III-V group compound semiconductor in which a V group element is common with that of said first semiconductor.

4. A light-emitting semiconductor device according to claim 2, wherein said first semiconductor is made of a III-V group compound semiconductor and said second semiconductor is made of a III-V group compound semiconductor in which a V group element is common with that of said first semiconductor.

5. A light-emitting semiconductor device according to claim 1, wherein said first semiconductor is made of AljGa₁-jAs, (0≦j), and said second semiconductor is made of AlkGa₁-kAs, (j<k≦1), and said electric current spreading layer is made of AlzGa₁-zAs, (0≦z≦1).

6. A light-emitting semiconductor device according to claim 2, wherein said first semiconductor is made of AljGa₁-jAs, (0≦j), and said second semiconductor is made of AlkGa₁-kAs, (j<k≦1), and said electric current spreading layer is made of AlzGa₁-zAs, (0≦z≦1).

7. A light-emitting semiconductor device according to claim 3, wherein said first semiconductor is made of AljGa₁-jAs, (0≦j), and said second semiconductor is made of AlkGa₁-kAs, (j<k≦1), and said electric current spreading layer is made of AlzGa₁-zAs, (0≦z≦1).

8. A light-emitting semiconductor device according to claim 4, wherein said first semiconductor is made of AljGa₁-jAs, (0≦j), and said second semiconductor is made of AlkGa₁-kAs, (j<k≦1), and said electric current spreading layer is made of AlzGa₁-zAs, (0≦z≦1).

9. A light-emitting semiconductor device according to claim 1, wherein said second reflection film is made of a III-V group compound semiconductor in which an average Al composition is not less than 0.4 and said electric current spreading layer is made of a III-V group compound semiconductor in which an Al composition is not less than 0.2.

10. A light-emitting semiconductor device according to claim 2, wherein said second reflection film is made of a III-V group compound semiconductor in which an average Al composition is not less than 0.4 and said electric current spreading layer is made of a III-V group compound semiconductor in which an Al composition is not less than 0.2.

11. A light-emitting semiconductor device according to claim 9, wherein said first semiconductor is made of AljGa₁-jAs, (0≦j), and said second semiconductor is made of AlkGa₁-kAs, (j<k≦1), and said electric current spreading layer is made of Ind(Ga₁-cAlc)₁-dP, (0<c≦1,0≦d<1).

12. A light-emitting semiconductor device according to claim 10, wherein said first semiconductor is made of AljGa₁-jAs, (0≦j), and said second semiconductor is made of AlkGa₁-kAs, (j<k ≦1), and said electric current spreading layer is made of Ind(Ga₁-cAlc)₁-dP, (0≦c≦1,0≦d<1).

13. A light-emitting semiconductor device according to claim 1, wherein the number of stacked pairs of said first and second semiconductors ranges from 4 to 12.

14. A light-emitting semiconductor device according to claim 3, wherein the number of stacked pairs of said first and second semiconductors ranges from 4 to 12.

15. A light-emitting semiconductor device according to claim 5, wherein the number of stacked pairs of said first and second semiconductors ranges from 4 to 12.

16. A light-emitting semiconductor device according to claim 7, wherein the number of stacked pairs of said first and second semiconductors ranges from 4 to 12.

17. A light-emitting semiconductor device according to claim 9, wherein the number of stacked pairs of said first and second semiconductors ranges from 4 to 12.

18. A light-emitting semiconductor device according to claim 11, wherein the number of stacked pairs of said first and second semiconductors ranges from 4 to 12.
